(19) United States
(12) Patent Application Publication
(10) Pub. No.: US 2011/0026228 A1
(43) Pub. Date: Feb. 3, 2011

(54) Retractable Circuit Board Guide And Bracket

(75) Inventors: Andrew Lafayette McAnally, Georgetown, TX (US); Vibora Sim, Pflugerville, TX (US); Steven George Sutter, Round Rock, TX (US)

Correspondence Address: HAYNES AND BOONE, LLP;IP Section, 2323 Victory Avenue, Suite 700, Dallas, TX, 75219, US

(73) Assignee: Dell Products L.P., Round Rock, TX (US)

(21) Appl. No.: 12/510,800

(22) Filed: Jul. 28, 2009

(51) Int. Cl. H05K 1/18; B23P 11/00

(52) U.S. Cl. 361/748; 29/428

(57) ABSTRACT

A circuit board guide and bracket apparatus includes a first member collapsibly attached to a second member. The first member is attachable to a planar member in a chassis. The second member guides a circuit board being mounted into a connector on the planar member and supports the board subsequent to being mounted.

### BACKGROUND

The present disclosure relates generally to information handling systems, and more particularly to a retractable circuit board guide and bracket for use in such systems.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Large circuit boards can pose alignment and installation difficulties to the user. Once installed the circuit boards can flex, and boards equipped with heavy components may be more vulnerable to shock and vibration effects. In space-constrained environments a fixed alignment device is not viable, due to component placement, thermal requirements, or package configuration for shipping.

Accordingly, it would be desirable to provide an improved collapsible circuit board guide and bracket device absent the disadvantages discussed above.

### SUMMARY

According to one embodiment, a circuit board guide and bracket includes a first member for attachment to a planar member. A second member is collapsibly attached to the first member. Means are provided on the secured member guiding a circuit board being mounted into a connector on the planar member and for supporting the board subsequent to being mounted.

### BRIEF DESCRIPTION OF THE DRAWINGS

FIG. 1 diagrammatically illustrates an embodiment of an IHS.

FIGS. 2, 3 and 4 illustrate an embodiment of a planar member including a bracket and a connector mounted thereon.

FIG. 5 illustrates an embodiment of a snap and rotating feature of the bracket.

FIG. 6 illustrates an embodiment of a circuit board mounted in the bracket and the connector.

FIG. 7 illustrates an embodiment of an expansion member connected to the circuit board.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

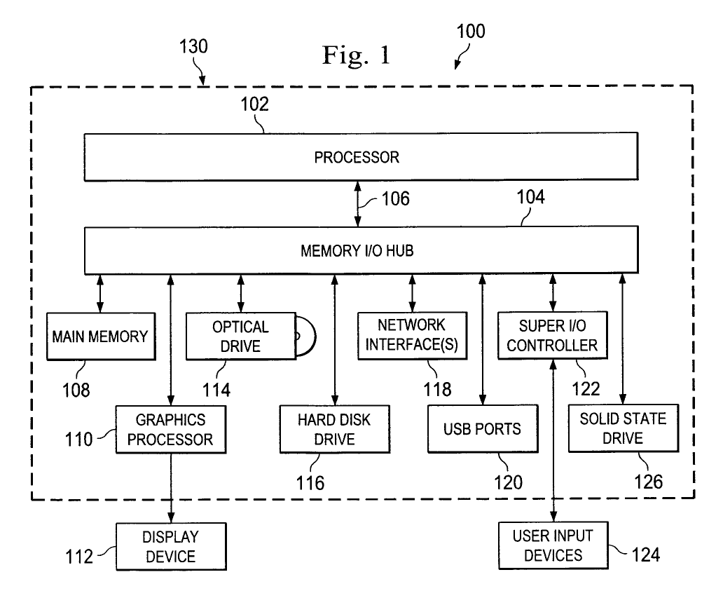

FIG. 1 is a block diagram of an IHS 100. The IHS 100 includes a processor 102 such as an Intel Pentium™ series processor or any other processor available. A memory I/O hub chipset 104 (comprising one or more integrated circuits) connects to processor 102 over a front-side bus 106. Memory I/O hub 104 provides the processor 102 with access to a variety of resources. Main memory 108 connects to memory I/O hub 104 over a memory or data bus. A graphics processor 110 also connects to memory I/O hub 104, allowing the graphics processor to communicate, e.g., with processor 102 and main memory 108. Graphics processor 110, in turn, provides display signals to a display device 112.

Other resources can also be coupled to the system through the memory I/O hub 104 using a data bus, including an optical drive 114 or other removable-media drive, one or more hard disk drives 116, one or more network interfaces 118, one or more Universal Serial Bus (USB) ports 120, and a super I/O controller 122 to provide access to user input devices 124, etc. The IHS 100 may also include a solid state drive (SSDs) 126 in place of, or in addition to main memory 108, the optical drive 114, and/or a hard disk drive 116. It is understood that any or all of the drive devices 114, 116 and 126 may be located locally with the IHS 100, located remotely from the IHS 100, and/or they may be virtual with respect to the IHS 100. Portions of the system 100 are provided in an IHS chassis 130, FIG. 1. Other parts of the system 100 such as display 112 and input devices 124, such as a mouse and a keyboard for example are peripherally attached to the system 100.

Not all IHSs 100 include each of the components shown in FIG. 1, and other components not shown may exist. Furthermore, some components shown as separate may exist in an integrated package or be integrated in a common integrated circuit with other components, for example, the processor 102 and the memory I/O hub 104 can be combined together. As can be appreciated, many systems are expandable, and include or can include a variety of components, including redundant or parallel resources.

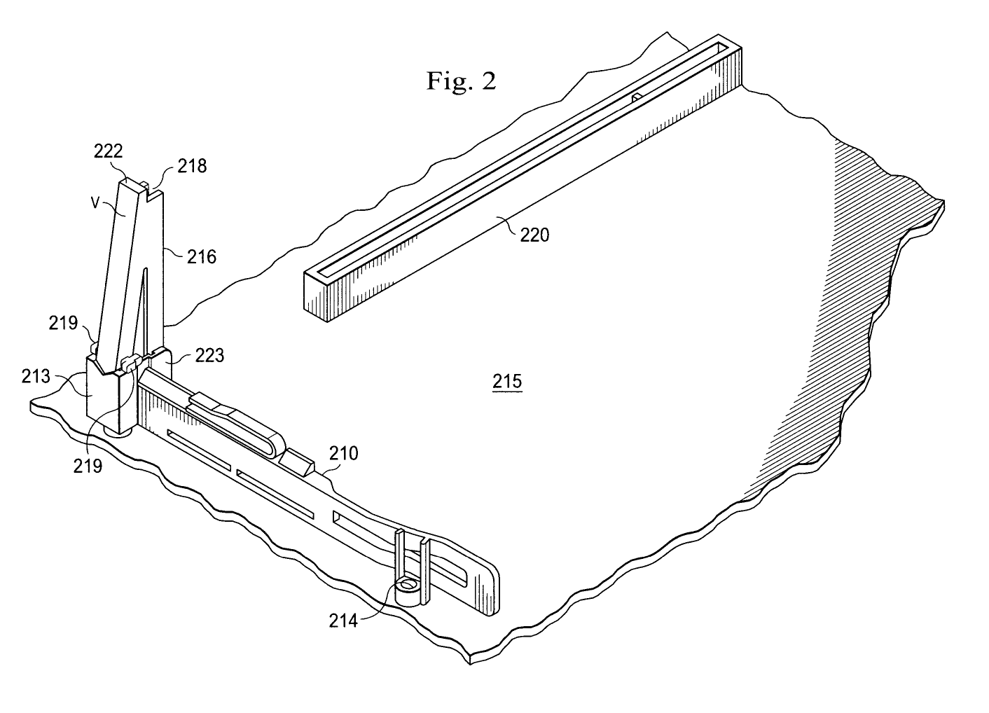

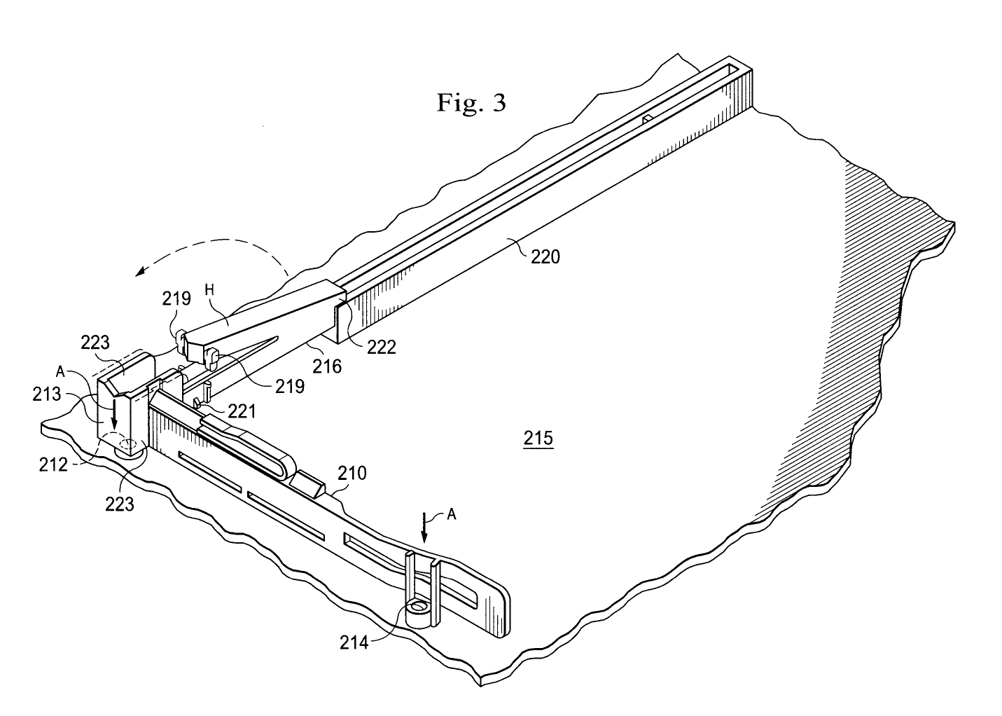

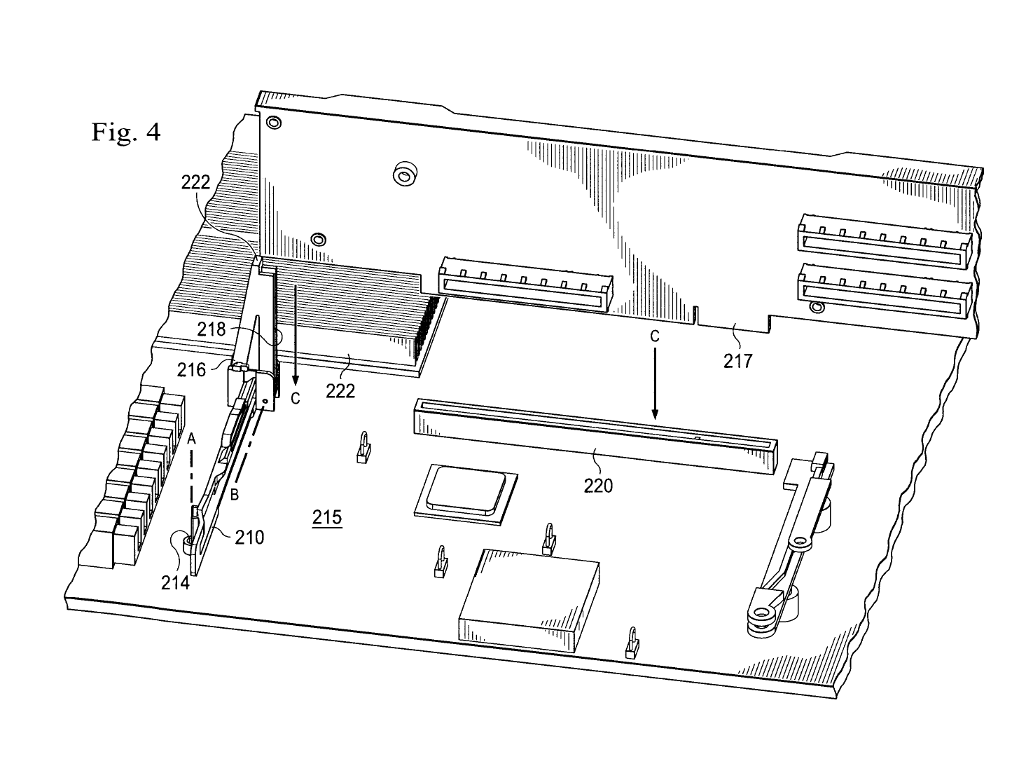

A circuit board guide and bracket FIGS. 2, 3 and 4, include a first member 210 including a means for attachment to a planar member such as a motherboard 215. The means for attachment includes an attachment aperture 212 formed in base 213 FIG. 3, and an aperture 214 formed on member 210, FIG. 4, provided in first member 210. A suitable fastener (not shown) may be applied by top-down insertion into the apertures 212, 214 in a direction indicated by directional arrow A.

A second member 216 is collapsibly attached to the first member 210, FIGS. 2, 3 and 4. In the illustrated embodiment, the collapsible attachment is a rotating attachment which rotates about an axis indicated by the line B. FIG. 4, permitting second member 216 to rotate or pivot between a first or vertical position V and a second or horizontal position H. It is contemplated that other attachments are possible which would be considered collapsible. The second member 216 includes means for guiding a circuit board 217, in a direction indicated by arrows designated C, which is being mounted into a connector 220 in the planar member as is discussed below. The means for guiding in this embodiment comprises an elongated groove 218 formed in the second member 216. When circuit board 217 is inserted into the groove 218, and mounted in connector 220, the board is supported subsequent to being mounted.

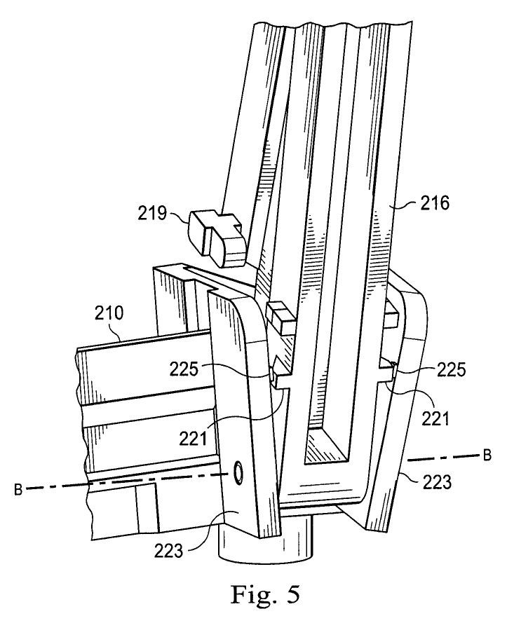

Rotation of member 216 FIGS. 2, 3 and 4, into the position H, permits member 216 to rest on connector 220 by means of a lip 222 formed on a distal end of member 216 adjacent groove 218. Rotation of member 216 into the position V, permits member 216 to snap into the vertical or extended position V by means of engagement of interacting opposed tab catch members 221 extending from opposite sides of second member 216 which engage with a pair of opposed snap tabs 225, FIGS. 3 and 5, which extend from flexible opposed sidewalls 223 of the base 213 of first member 210. The flexible sidewalls 223 are illustrated as flexed apart as indicated by dotted line in FIG. 3. Also, when member 216 is fully rotated into position V, a pair of opposed stops 219 extending from opposite sides of second member 216, seat on the sidewalls 223.

In further detail, the snap feature includes the catch tabs 221, FIG. 5, extending from opposite sides of second member 216 which engage snap tabs 225 which extend from flexible sidewalls 223. As can be seen in FIG. 5, rotation of second member 216 about axis B, causes an interference engagement of tabs 221 and 225 which flex the sidewalls 223 sufficiently to permit relative rotation of members 216 and 210, and then hold member 216 in either of the positions V and H, as discussed above.

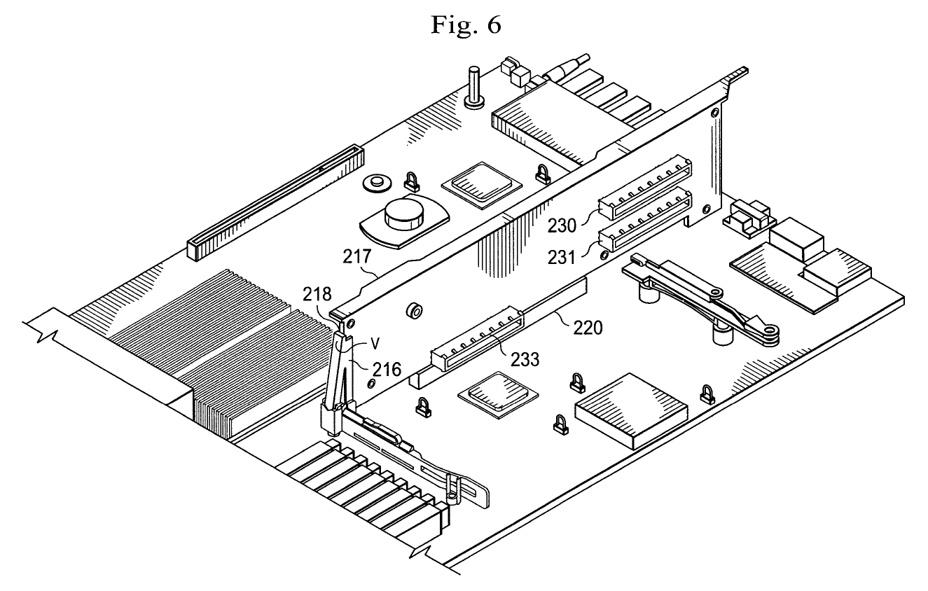

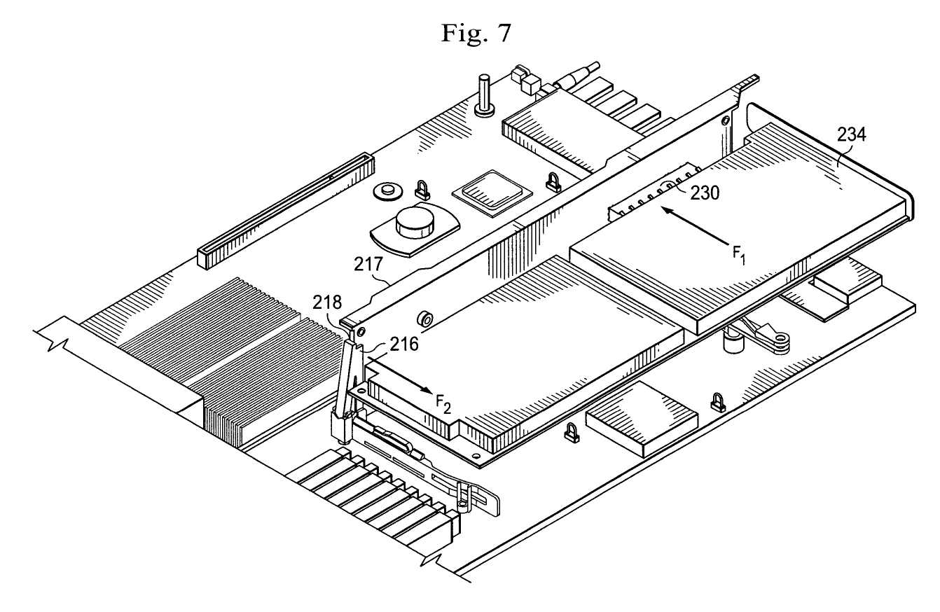

In FIG. 6, board 217 is mounted in connector 220 and is supported in position V in groove 218 of second bracket member 216. Also included on board 217, are exemplary additional connectors 230, 231 and 233, which can receive additional plug-in devices such as an expansion member 234, FIG. 7. As it can be seen in FIG. 7, a force F₁ exerted toward board 217, where member 234 is plugged into connector 230, is counteracted at least in part by a force F₂ due to board 217 being seated and supported in groove 218 of member 216.

The disclosed device provides positive guidance of circuit boards during insertion and removal, provides rigid support of the board once installed, and is able to retract into a low-profile configuration when not in use (as in shipping). The device may be affixed to a planar or motherboard assembly, thereby limiting the need for an external bracket.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

1. A circuit board guide and bracket apparatus comprising:
a first member including means for attachment to a planar member; and
a second member collapsibly attached to the first member, the second member including means for guiding a circuit board being mounted into a connector on the planar member and for supporting the board subsequent to being mounted.

2. The apparatus of claim 1, wherein the second member is rotatably attached to the first member.

3. The apparatus of claim 2, further comprising:
a circuit board receiving groove formed in the second member.

4. The apparatus of claim 3, wherein the second member is moved from a collapsed position to an extended position for receiving the circuit board in the groove and for stabilizing the board in the connector.

5. The apparatus of claim 4, further comprising:
a snap-in receiver on the first member adjacent the rotatable attachment.

6. The apparatus of claim 5, wherein the snap-in receiver includes a pair of opposed flexible spaced-apart members.

7. The apparatus of claim 6, further comprising:
a pair of opposed tabs on the second member rotatable into engagement with the opposed flexible members.

8. An information handling system (IHS) comprising:
a chassis;
a planar member mounted in the chassis;
a processor mounted on the planar member;
a memory coupled to the processor; and
a circuit board guide and bracket mounted on the planar member including:
a first member including means for attachment to the planar member; and
a second member collapsibly attached to the first member, the second member including means for guiding a circuit board being mounted into a connector on the planar member and for supporting the board subsequent to being mounted.

9. The system of claim 8, wherein the second member is rotatably attached to the first member.

10. The system of claim 8, further comprising:
a circuit board receiving groove formed in the second member.

11. The system of claim 10, wherein the second member is moved from collapsed position to an extended position for receiving the circuit board in the groove and for stabilizing the board in the connector.

12. The system of claim 8, further comprising:
a snap-in receiver on the first member adjacent the attachment to the second member.

13. The system of claim 12, wherein the snap-in receiver includes a pair of opposed flexible spaced apart members.

14. The system of claim 13, further comprising:
a pair of opposed tabs on the second member rotatable into engagement with the opposed flexible members.

15. A method for guiding and supporting a circuit board in a chassis comprising:
providing a chassis;
mounting a planar member in the chassis, the planar member including a connector;
attaching a first guide bracket member to the planar member adjacent the connector;
attaching a collapsible second guide bracket member to the first member;
providing, on the second member, means for guiding and supporting a circuit board; and
inserting the circuit board into the second member and the connector.

16. The method of claim 15, further comprising:
prior to the inserting, extending the second guide bracket member from a collapsed position for receiving the circuit board.

17. The method of claim 15, further comprising:
providing, on the second guide member, a circuit board receiving groove.

18. The method of claim 15, further comprising:
rotatably attaching the second guide bracket member to the first guide bracket member.

19. The method of claim 15, further comprising:
providing a pair of opposed flexible spaced apart members on the first member.

20. The method of claim 19, further comprising:
providing a pair of opposed tabs on the second member, rotatable into engagement with the opposed flexible members.
